(19) United States
(12) Patent Application Publication
(10) Pub. No.: US 2012/0049148 A1
(43) Pub. Date: Mar. 1, 2012

(54) THREE-DIMENSIONAL NONVOLATILE SEMICONDUCTOR MEMORY

(76) Inventor: Gou FUKANO, Tokyo (JP)

(21) Appl. No.: 13/222,209

(22) Filed: Aug. 31, 2011

(30) Foreign Application Priority Data
Aug. 31, 2010 (JP) 2010-194622

(51) Int. Cl. H01L 45/00

(52) U.S. Cl. 257/5; 257/E45.001

(57) ABSTRACT

According to one embodiment, a three-dimensional nonvolatile semiconductor memory includes a semiconductor substrate, a memory cell array includes memory cells stacked on the semiconductor substrate and first conductive layers connected to the memory cells, a dummy stacked layer structure includes second conductive layers stacked on the semiconductor substrate, and surrounding the memory cell array, and a metal layer provided on the memory cell array and the dummy stacked layer structure. The second conductive layers are fixed on a ground potential.

### CROSS-REFERENCE TO RELATED APPLICATIONS

This application is based upon and claims the benefit of priority from prior Japanese Patent Application No. 2010-194622, filed Aug. 31, 2010, the entire contents of which are incorporated herein by reference.

### FIELD

Embodiments described herein relate generally to a three-dimensional nonvolatile semiconductor memory.

### BACKGROUND

A three-dimensional nonvolatile semiconductor memory such as a resistance change memory or a BiCS (Bit Cost Scalability)-NAND is expected to be a next-generation semiconductor memory capable of implementing a mass capacity. The resistance change memory is a memory that stores, in a nonvolatile manner, data in a material the resistance value of which changes according to a voltage, a current, heat, or the like, and includes a phase change memory and a magnetic random access memory.

In such a three-dimensional nonvolatile semiconductor memory, a three-dimensional memory cell array is formed by stacking memory cell arrays on a semiconductor substrate. However, it is difficult to form three-dimensional peripheral circuits for controlling the read/write operation in the three-dimensional memory cell array.

To do this, a dummy stacked layer structure having the same structure as that of the three-dimensional memory cell array is provided on the semiconductor substrate. This allows to planarize the three-dimensional memory cell array and the dummy stacked layer structure and lay out conductive lines such as a power supply line on them.

### BRIEF DESCRIPTION OF THE DRAWINGS

FIG. 1 is a block diagram showing a three-dimensional nonvolatile semiconductor memory;

FIG. 2 is a perspective view showing the memory cell array of a resistance change memory;

FIG. 3 is a perspective view showing cell units;

FIGS. 4 and 5 are perspective views showing a memory cell array and peripheral circuits;

FIG. 6 is a plan view showing a device structure;

FIG. 7 is a sectional view taken along a line VII-VII in FIG. 6;

FIG. 8 is a sectional view taken along a line VIII-VIII in FIG. 6;

FIGS. 9 and 10 are sectional views of the memory cell arrays and a dummy stacked layer structure;

FIG. 11 is a plan view of the dummy stacked layer structure;

FIGS. 12, 13, 14, and 15 are sectional views of the dummy stacked layer structure;

FIGS. 16 and 17 are sectional views of the memory cell arrays and the dummy stacked layer structure;

FIG. 18 is a plan view of the dummy stacked layer structure;

FIGS. 19, 20, and 21 are sectional views of the dummy stacked layer structure;

FIGS. 22 and 23 are plan views showing the layout of contact portions;

FIGS. 24 and 25 are plan views showing details of FIGS. 22 and 23;

FIG. 26 is a plan view showing the layout of contact portions;

FIGS. 27 and 28 are plan views showing details of FIG. 26;

FIGS. 29, 30, and 31 are plan views showing the layout of contact portions; and

FIG. 32 is a sectional view showing the dummy stacked layer structure of a BiCS-NAND.

### DETAILED DESCRIPTION

A dummy stacked layer structure electrically floats because it is not connected to the peripheral circuits. In addition, unexpected charges may be stored in the dummy stacked layer structure during the manufacturing process of the three-dimensional nonvolatile semiconductor memory or during the test/normal operation. In particular, in the manufacturing process of a three-dimensional nonvolatile semiconductor memory, CMP (Chemical Mechanical Polishing) is used many times for planarization. During the CMP, charges are stored in the dummy stacked layer structure.

The charges stored in the dummy stacked layer structure generate a leak current or an unnecessary coupling capacitance during read/write, leading to reliability degradation caused by operation errors.

In general, according to one embodiment, a three-dimensional nonvolatile semiconductor memory comprising: a semiconductor substrate; a memory cell array comprising memory cells stacked on the semiconductor substrate and first conductive layers connected to the memory cells; a dummy stacked layer structure comprising second conductive layers stacked on the semiconductor substrate, and surrounding the memory cell array; and a metal layer provided on the memory cell array and the dummy stacked layer structure, wherein the second conductive layers are fixed at a ground potential.

In the following embodiments, a resistance change memory and a BiCS-NAND will be explained as representative examples of a three-dimensional nonvolatile semiconductor memory.

### 1. General View

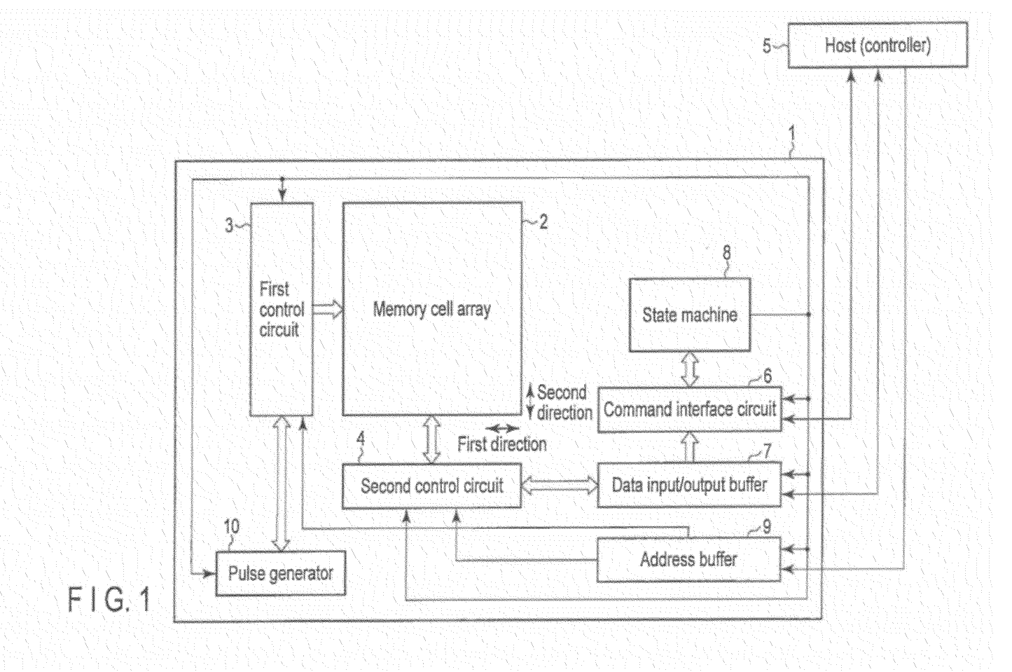

FIG. 1 shows the main portion of a three-dimensional nonvolatile semiconductor memory.

Three-dimensional nonvolatile semiconductor memory (for example, chip) 1 includes memory cell array 2 comprising memory cells stacked on a semiconductor substrate.

When three-dimensional nonvolatile semiconductor memory 1 is a resistance change memory, memory cell array 2 has, for example, a cross-point type cell array structure. When three-dimensional nonvolatile semiconductor memory 1 is a BiCS-NAND, memory cell array 2 has, for example, a NAND cell array formed into a semiconductor column extending through conductive layers.

First control circuit 3 is provided at one end of memory cell array 2 in the first direction. Second control circuit 4 is provided at one end in the second direction intersecting the first direction.

First and second control circuits 3 and 4 select one of stacked memory cells based on, for example, a memory cell array selection signal.

First control circuit 3 selects a row of memory cell array 2 based on, for example, a row address signal. Second control circuit 4 selects a column of memory cell array 2 based on, for example, a column address signal.

First and second control circuits 3 and 4 control data write/erase/read for the memory cells in memory cell array 2.

First and second control circuits 3 and 4 can perform data write/erase/read for one of the stacked memory cells, or simultaneously execute data write/erase/read for two or more or all of the stacked memory cells.

Host (controller) 5 supplies control signals and data to three-dimensional nonvolatile semiconductor memory 1. A control signal is input to command interface circuit 6. Data is input to data input/output buffer 7.

Host 5 may be provided in chip 1 or in a chip (for example, microcomputer) different from chip 1.

Command interface circuit 6 determines based on a control signal whether data from host 5 is command data. If the data is command data, it is transferred from data input/output buffer 7 to state machine 8.

State machine 8 manages the operation of three-dimensional nonvolatile semiconductor memory 1 based on the command data. For example, state machine 8 manages data write/erase/read based on the command data from host 5.

Host 5 can also receive status information managed by state machine 8 and determine the operation result of three-dimensional nonvolatile semiconductor memory 1.

In the write/erase/read operation, host 5 supplies an address signal to three-dimensional nonvolatile semiconductor memory 1. The address signal includes, for example, a memory cell array selection signal, a row address signal, and a column address signal.

The address signals are input to first and second control circuits 3 and 4 through address buffer 9.

Pulse generator 10 outputs a voltage pulse or a current pulse necessary for, for example, the write/erase/read operation at a predetermined timing based on an instruction from state machine 8.

### 2. Resistance Change Memory

An example of the resistance change memory will be described below.

### (1) Memory Cell Array

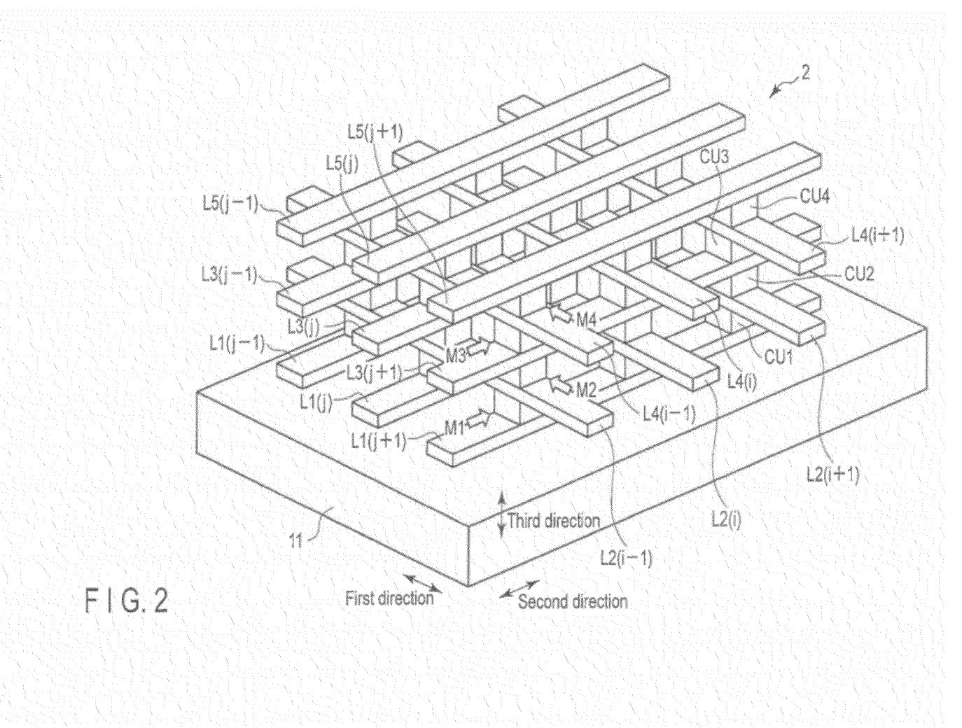

FIG. 2 shows the memory cell array of the resistance change memory.

Cross-point type memory cell array 2 is provided on semiconductor substrate (for example, silicon substrate) 11. Note that an element such as a MOS transistor or an insulating layer may be sandwiched between cross-point type memory cell array 2 and semiconductor substrate 11.

FIG. 2 illustrates an example in which cross-point type memory cell array 2 is formed from four memory cell arrays M1, M2, M3, and M4 stacked in the third direction (a direction perpendicular to the major surface of semiconductor substrate 11). The number of memory cell arrays stacked need only be two or more.

Memory cell array M1 includes cell units CU1 provided in an array in the first and second directions.

Similarly, memory cell array M2 includes cell units CU2 provided in an array, memory cell array M3 includes cell units CU3 provided in an array, and memory cell array M4 includes cell units CU4 provided in an array.

Each of cell units CU1, CU2, CU3, and CU4 includes a memory cell (resistance change element) and a rectifying element which are connected in series.

Conductive lines L1(j−1), L1(j), and L1(j+1), conductive lines L2(i−1), L2(i), and L2(i+1), conductive lines L3(j−1), L3(j), and L3(j+l), conductive lines L4(i−1), L4(i), and L4(i+1), and conductive lines L5(j−1), L5(j), and L5(j+1) are provided on semiconductor substrate 11 in this order from the side of semiconductor substrate 11.

The odd-numbered conductive lines from the side of semiconductor substrate 11, that is, conductive lines L1(j−1), L1(j), and L1(j+1), conductive lines L3(j−1), L3(j), and L3(j+1), and conductive lines L5(j−1), L5(j), and L5(j+1) run in the second direction.

The even-numbered conductive lines from the side of semiconductor substrate 11, that is, conductive lines L2(i−1), L2(i), and L2(i+1) and conductive lines L4(i−1), L4(i), and L4(i+1) run in the first direction.

These conductive lines function as word lines or bit lines.

Lowermost, first memory cell array M1 is provided between first conductive lines L1(j−1), L1(j), and L1(j+1) and second conductive lines L2(i−1), L2(i), and L2(i+1). In the write/erase/read operation for memory cell array M1, one of the group of conductive lines L1(j−1), L1(j), and L1(j+1) and the group of conductive lines L2(i−1), L2(i), and L2(i+1) functions as word lines, and the other functions as bit lines.

Memory cell array M2 is provided between second conductive lines L2(i−1), L2(i), and L2(i+1) and third conductive lines L3(j−1), L3(j), and L3(j+1). In the write/erase/read operation for memory cell array M2, one of the group of conductive lines L2(i−1), L2(i), and L2(i+1) and the group of conductive lines L3(j−1), L3(j), and L3(j+1) functions as word lines, and the other functions as bit lines.

Memory cell array M3 is provided between third conductive lines L3(j−1), L3(j), and L3(j+1) and fourth conductive lines L4(i−1), L4(i), and L4(i+1). In the write/erase/read operation for memory cell array M3, one of the group of conductive lines L3(j−1), L3(j), and L3(j+1) and the group of conductive lines L4(i−1), L4(i), and L4(i+1) functions as word lines, and the other functions as bit lines.

Memory cell array M4 is provided between fourth conductive lines L4(i−1), L4(i), and L4(i+1) and fifth conductive lines L5(j−1), L5(j), and L5(j+1). In the write/erase/read operation for memory cell array M4, one of the group of conductive lines L4(i−1), L4(i), and L4(i+1) and the group of conductive lines L5(j−1), L5(j), and L5(j+1) functions as word lines, and the other functions as bit lines.

### (2) Cell Unit

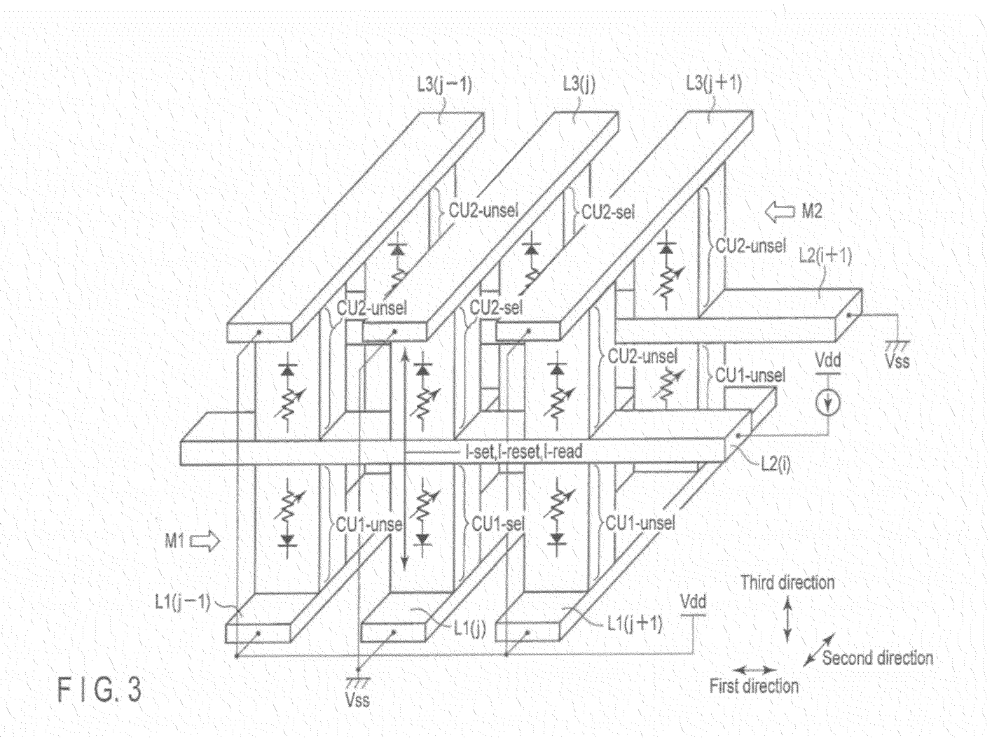

FIG. 3 shows the cell units in two memory cell arrays.

FIG. 3 illustrates, for example, cell units CU1 and CU2 in two memory cell arrays M1 and M2 shown in FIG. 2. In this case, the cell units in two memory cell arrays M3 and M4 shown in FIG. 2 have the same structure as that of the cell units in two memory cell arrays M1 and M2 shown in FIG. 2.

Each of cell units CU1 and CU2 includes a memory cell (resistance change element) and a rectifying element which are connected in series.

The memory cell and the rectifying element can have a connection relationship in various patterns.

However, the connection relationship between the memory cell and the rectifying element needs to be the same among all cell units in one memory cell array.

### (3) Operation

The operation of the above-described resistance change memory will be described with reference to FIG. 3.

Memory cell array M1 corresponds to memory cell array M1 in FIG. 2, and memory cell array M2 corresponds to memory cell array M2 in FIG. 2.

For the resistance change memory, for example, write will be referred to as set, and erase as reset. The resistance value in the set state need only be different from that in the reset state. Whether the resistance is higher or lower is not important.

A multi-level resistance change memory in which one memory cell stores multi-level data can be implemented by selectively writing one of resistance values in the set operation.

### A. Set Operation

Performing the write (set) operation for selected cell unit CU1-sel in memory cell array M1 and selected cell unit CU2-sel in memory cell array M2 will be explained first.

The initial state of selected cell units CU1-sel and CU2-sel is the erase (reset) state. The reset state is defined as the high resistance state (100 kΩ to 1 MΩ), and the set state is defined as the low resistance state (1 kΩ to 10 kΩ).

Selected conductive line L2(i) is connected to power supply potential Vdd on the high potential side. Selected conductive lines L1(j) and L3(j) are connected to ground potential Vss on the low potential side.

Out of the first conductive lines from the semiconductor substrate side, remaining unselected conductive lines L1(j−1) and L1(j+1) other than selected conductive line L1(j) are connected to power supply potential Vdd.

Out of the second conductive lines from the semiconductor substrate side, remaining unselected conductive line L2(i+1) other than selected conductive line L2(i) is connected to ground potential Vss.

Out of the third conductive lines from the semiconductor substrate side, remaining unselected conductive lines L3(j−1) and L3(j+1) other than selected conductive line L3(j) are connected to power supply potential Vdd.

At this time, a forward bias is applied to the rectifying elements (diodes) in selected cell units CU1-sel and CU2-sel. For this reason, set current I-set from the constant current source flows to selected cell units CU1-sel and CU2-sel so that the resistance value of the memory cells in selected cell units CU1-sel and CU2-sel changes from the high resistance state to the low resistance state.

In the set operation, a voltage of 1 to 2 V is applied to the memory cells in selected cell units CU1-sel and CU2-sel. The current density of set current I-set flowing to the memory cells (high resistance state) is set to a value within the range of 1×10⁵ to 1×10⁷ A/cm².

On the other hand, a reverse bias is applied to the rectifying elements (diodes) in the cell units connected between unselected conductive lines L1(j−1) and L1(j+1) and unselected conductive line L2(i+1) out of unselected unit cells CU1-unsel in the memory cell array M1.

Similarly, a reverse bias is applied to the rectifying elements (diodes) in the cell units connected between unselected conductive lines L3(j−1) and L3(j+1) and unselected conductive line L2(i+1) out of unselected unit cells CU2-unsel in the memory cell array M2.

No bias is applied to the rectifying elements (diodes) in the cell units connected between selected conductive line L2(i) and unselected conductive lines L1(j−1) and L1(j+1) and the rectifying elements (diodes) in the cell units connected between unselected conductive line L2(i+1) and selected conductive line L1(j) out of unselected unit cells CU1-unsel in the memory cell array M1.

Similarly, no bias is applied to the rectifying elements (diodes) in the cell units connected between selected conductive line L2(i) and unselected conductive lines L3(j−1) and L3(j+1) and the rectifying elements (diodes) in the cell units connected between unselected conductive line L2(i+1) and selected conductive line L3(j) out of unselected unit cells CU2-unsel in the memory cell array M2.

Hence, the set operation is not performed for the memory cells in unselected unit cells CU1-unsel and CU2-unsel.

### B. Reset Operation

Performing the erase (reset) operation for selected cell unit CU1-sel in memory cell array M1 and selected cell unit CU2-sel in memory cell array M2 will be explained next.

Selected conductive line L2(i) is connected to power supply potential Vdd on the high potential side. Selected conductive lines L1(j) and L3(j) are connected to ground potential Vss on the low potential side.

Out of the first conductive lines from the semiconductor substrate side, remaining unselected conductive lines L1(j−1) and L1(j+1) other than selected conductive line L1(j) are connected to power supply potential Vdd.

Out of the second conductive lines from the semiconductor substrate side, remaining unselected conductive line L2(i+1) other than selected conductive line L2(i) is connected to ground potential Vss.

Out of the third conductive lines from the semiconductor substrate side, remaining unselected conductive lines L3(j−1) and L3(j+1) other than selected conductive line L3(j) are connected to power supply potential Vdd.

At this time, a forward bias is applied to the rectifying elements (diodes) in selected cell units CU1-sel and CU2-sel. For this reason, reset current I-reset from the constant current source flows to selected cell units CU1-sel and CU2-sel so that the resistance value of the memory cells in selected cell units CU1-sel and CU2-sel changes from the low resistance state to the high resistance state.

In the reset operation, a voltage of 1 to 3 V is applied to the memory cells in selected cell units CU1-sel and CU2-sel. The current density of reset current I-reset flowing to the memory cells (low resistance state) is set to a value within the range of 1×10³ to 1×10⁶ A/cm².

On the other hand, a reverse bias is applied to the rectifying elements (diodes) in the cell units connected between unselected conductive lines L1(j−1) and L1(j+1) and unselected conductive line L2(i+1) out of unselected unit cells CU1-unsel in the memory cell array M1.

Similarly, a reverse bias is applied to the rectifying elements (diodes) in the cell units connected between unselected conductive lines L3(j−1) and L3(j+1) and unselected conductive line L2(i+1) out of unselected unit cells CU2-unsel in the memory cell array M2.

No bias is applied to the rectifying elements (diodes) in the cell units connected between selected conductive line L2(i) and unselected conductive lines L1(j−1) and L1(j+1) and the rectifying elements (diodes) in the cell units connected between unselected conductive line L2(i+1) and selected conductive line L1(j) out of unselected unit cells CU1-unsel in the memory cell array M1.

Similarly, no bias is applied to the rectifying elements (diodes) in the cell units connected between selected conductive line L2(i) and unselected conductive lines L3(j−1) and L3(j+1) and the rectifying elements (diodes) in the cell units connected between unselected conductive line L2(i+1) and selected conductive line L3(j) out of unselected unit cells CU2-unsel in the memory cell array M2.

Hence, the reset operation is not performed for the memory cells in unselected unit cells CU1-unsel and CU2-unsel.

Note that set current I-set and reset current I-reset are different from each other. The voltage value applied to the memory cells in selected cell units CU1-sel and CU2-sel to generate those currents depends on the material of the memory cells.

### C. Read Operation

Performing the read operation for selected cell unit CU1-sel in memory cell array M1 and selected cell unit CU2-sel in memory cell array M2 will be explained next.

Selected conductive line L2(i) is connected to power supply potential Vdd on the high potential side. Selected conductive lines L1(j) and L3(j) are connected to ground potential Vss on the low potential side.

Out of the first conductive lines from the semiconductor substrate side, remaining unselected conductive lines L1(j−1) and L1(j+1) other than selected conductive line L1(j) are connected to power supply potential Vdd.

Out of the second conductive lines from the semiconductor substrate side, remaining unselected conductive line L2(i+1) other than selected conductive line L2(i) is connected to ground potential Vss.

Out of the third conductive lines from the semiconductor substrate side, remaining unselected conductive lines L3(j−1) and L3(j+1) other than selected conductive line L3(j) are connected to power supply potential Vdd.

At this time, a forward bias is applied to the rectifying elements (diodes) in selected cell units CU1-sel and CU2-sel. For this reason, read current I-read from the constant current source flows to memory cells (high resistance state or low resistance state) in selected cell units CU1-sel and CU2-sel.

Hence, for example, detecting the potential change in the sense node when read current I-read flows to the memory cells enables to read data (resistance value) of the memory cells.

The value of read current I-read needs to be much smaller than that of set current I-set and that of reset current I-reset so that the resistance value of the memory cells at the time of read is not changed.

In the read as well, a reverse bias is applied to the rectifying elements (diodes) in the cell units connected between unselected conductive lines L1(j−1) and L1(j+1) and unselected conductive line L2(i+1) out of unselected unit cells CU1-unsel in the memory cell array M1, as in the set/reset.

Similarly, a reverse bias is applied to the rectifying elements (diodes) in the cell units connected between unselected conductive lines L3(j−1) and L3(j+1) and unselected conductive line L2(i+1) out of unselected unit cells CU2-unsel in the memory cell array M2.

No bias is applied to the rectifying elements (diodes) in the cell units connected between selected conductive line L2(i) and unselected conductive lines L1(j−1) and L1(j+1) and the rectifying elements (diodes) in the cell units connected between unselected conductive line L2(i+1) and selected conductive line L1(j) out of unselected unit cells CU1-unsel in the memory cell array M1.

Similarly, no bias is applied to the rectifying elements (diodes) in the cell units connected between selected conductive line L2(i) and unselected conductive lines L3(j−1) and L3(j+1) and the rectifying elements (diodes) in the cell units connected between unselected conductive line L2(i+1) and selected conductive line L3(j) out of unselected unit cells CU2-unsel in the memory cell array M2.

Hence, the read operation is not performed for the memory cells in unselected unit cells CU1-unset and CU2-unsel.

### (4) Other

To change the resistance value of a memory cell, two methods are available. One method changes the polarity of the voltage to be applied to the memory cell so as to reversibly change the resistance value of the memory cell at least between a first value and a second value. The other method controls the magnitude and application time of the voltage without changing the polarity of the voltage to be applied to the memory cell so as to reversibly change the resistance value of the memory cell at least between a first value and a second value.

The former is called a bipolar operation. The latter is called a unipolar operation. The resistance change memory according to this embodiment is applicable to both the bipolar operation and the unipolar operation.

### 3. Memory Cell Array and Peripheral Circuits

### (1) Layout

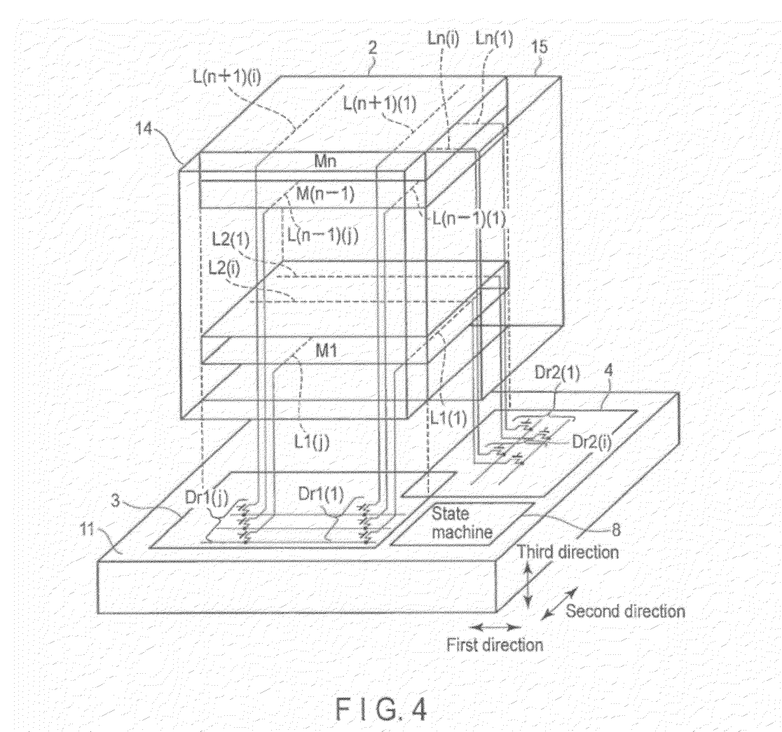

FIG. 4 illustrates the first example of the memory cell array and the peripheral circuits.

Semiconductor substrate 11 has n (n is a natural number of 2 or more) memory cell arrays 2 stacked on it. An example in which n is an even number of 4 or more will be described here for descriptive convenience.

Odd-numbered conductive lines L1(j), . . . , L(n−1)(j), L(n+1)(j) run in the second direction. One end of each of the conductive lines is connected to a corresponding one of drivers (FET) Dr1(j) in first control circuit 3 through hookup area 14. Drivers (FET) Dr1(j) are two-dimensionally formed in a limited region on semiconductor substrate 11.

Even-numbered conductive lines L2(i), . . . , Ln(i) run in the first direction. One end of each of the conductive lines is connected to a corresponding one of drivers (FET) Dr2(i) in second control circuit 4 through hookup area 15. Drivers (FET) Dr2(j) are also two-dimensionally formed in a limited region on semiconductor substrate 11.

State machine 8 manages the operation of first and second control circuits 3 and 4 based on command data.

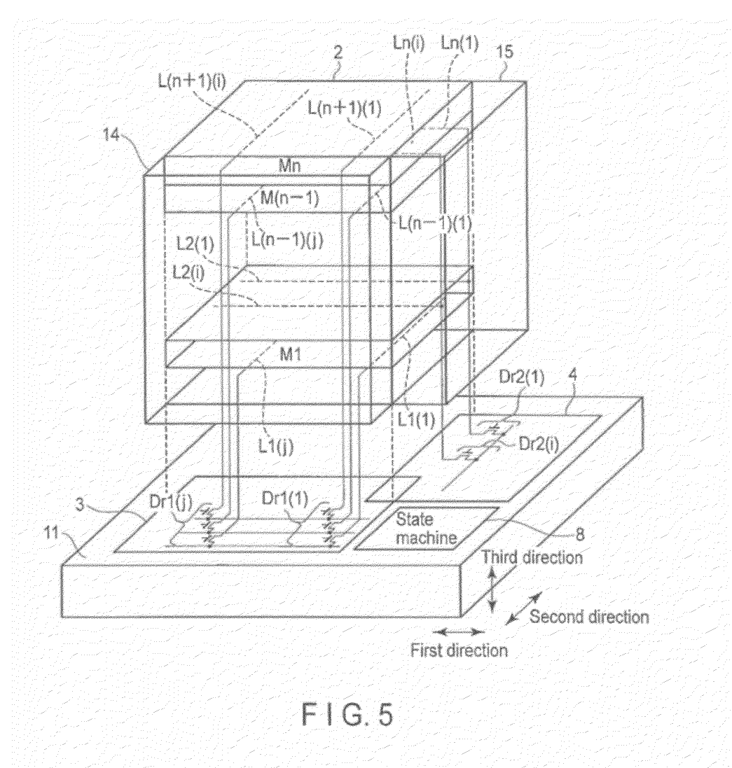

FIG. 5 illustrates the second example of the memory cell array and the peripheral circuits.

As the feature of the second example, the even-numbered conductive lines L2(i), . . . , Ln(i) share one driver (FET) Dr2(i), unlike the first example.

That is, even-numbered conductive lines L2(i), . . . , Ln(i) run in the first direction. One end of each of the conductive lines is commonly connected to driver (FET) Dr2(i) in second control circuit 4. Driver (FET) Dr2(j) is two-dimensionally formed in a limited region on semiconductor substrate 11.

The other components denoted by the same reference numerals as in FIG. 4 are the same as in the first example, and a detailed description thereof will be omitted.

### (2) Device Structure

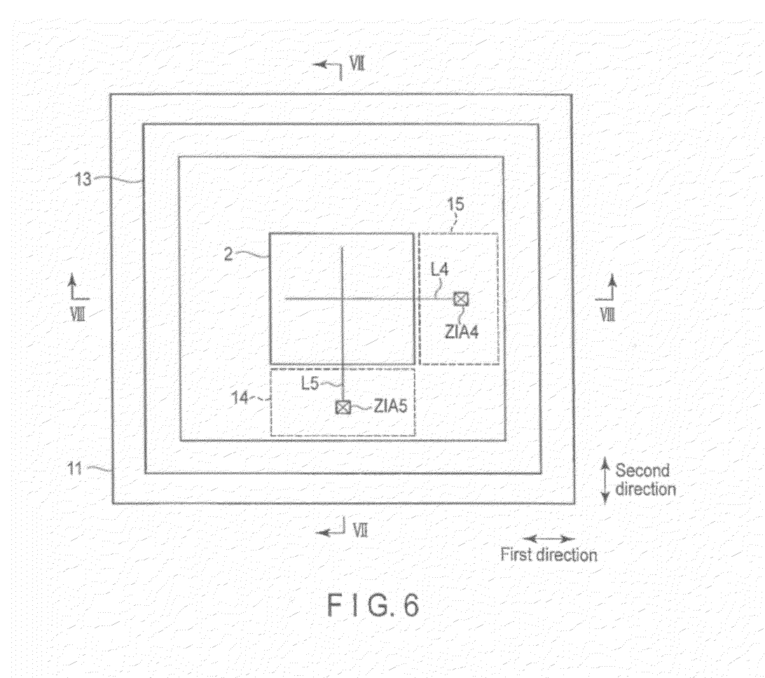

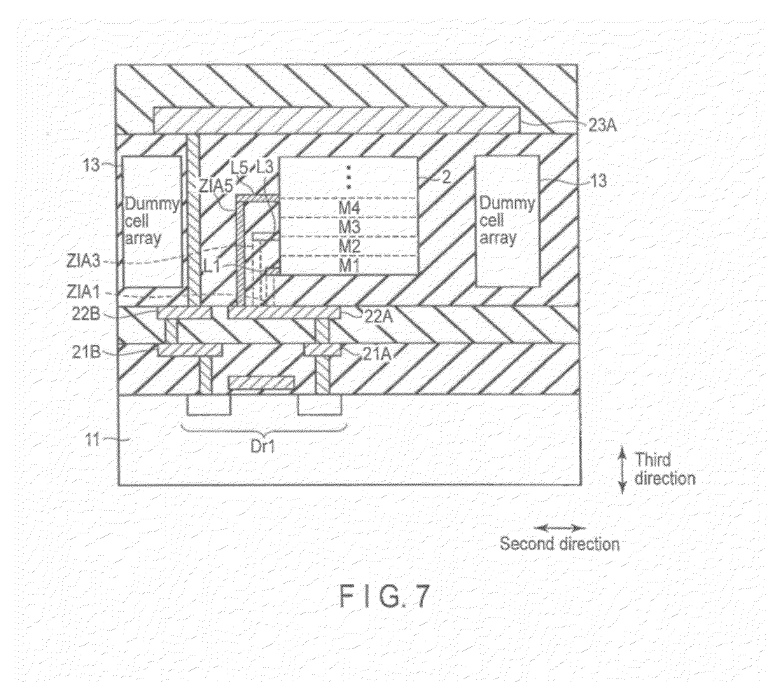

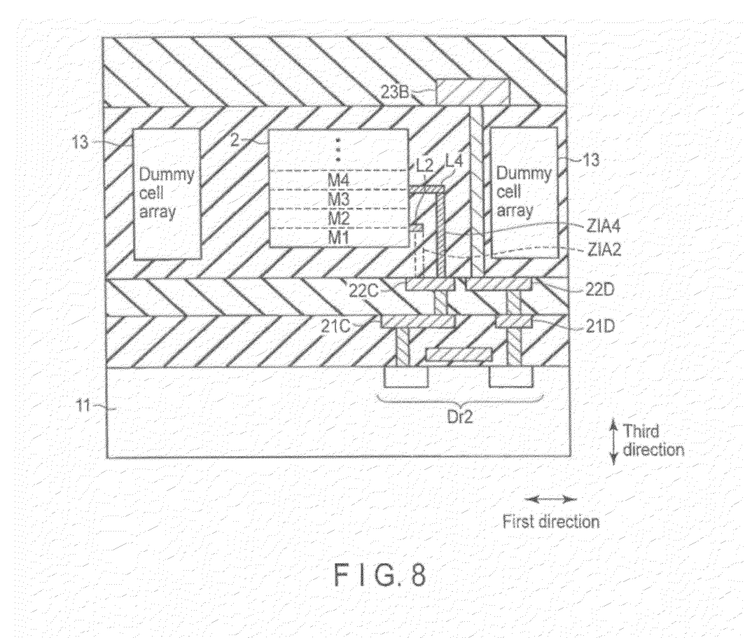

FIGS. 6, 7, and 8 show an example of the device structure. FIG. 6 is a plan view, FIG. 7 is a sectional view taken along a line VII-VII in FIG. 6, and FIG. 8 is a sectional view taken along a line VIII-VIII in FIG. 6.

Drivers (FET) Dr1 and Dr2 are provided on semiconductor substrate 11. Memory cell array 2 and dummy stacked layer structure 13 are provided above semiconductor substrate 11.

Dummy stacked layer structure 13 surrounds memory cell array 2. Dummy stacked layer structure 13 has the same structure as that of memory cell array 2 and is provided to planarize the upper surface of the insulating layer on memory cell array 2 and dummy stacked layer structure 13.

Odd-numbered conductive lines L1, L3, L5, . . . from the side of semiconductor substrate 11 will be explained.

Fifth conductive line L5 from the side of semiconductor substrate 11 serves as the upper conductive line of memory cell array M4 and runs in the second direction. One end of conductive line L5 is connected to via ZIA5 in hookup area 14. Via ZIA5 connects conductive line 22A to conductive line L5. Conductive line 22A is connected to one terminal of driver Dr1 through conductive line 21A. The other terminal of driver Dr1 is connected to conductive line 23A through conductive lines 21B and 22B.

Third conductive line L3 from the side of semiconductor substrate 11 serves as the upper conductive line of memory cell array M2 and the lower conductive line of memory cell array M3 and runs in the second direction. One end of conductive line L3 is connected to via ZIA3. First conductive line L1 from the side of semiconductor substrate 11 serves as the lower conductive line of memory cell array M1 and runs in the second direction. One end of conductive line L1 is connected to via ZIA1.

Even-numbered conductive lines L2, L4, . . . from the side of semiconductor substrate 11 will be explained.

Fourth conductive line L4 from the side of semiconductor substrate 11 serves as the upper conductive line of memory cell array M3 and the lower conductive line of memory cell array M4 and runs in the first direction. One end of conductive line L4 is connected to via ZIA4 in hookup area 15. Via ZIA4 connects conductive line 22C to conductive line L4. Conductive line 22C is connected to one terminal of driver Dr2 through conductive line 21C. The other terminal of driver Dr2 is connected to conductive line 23B through conductive lines 21D and 22D.

Second conductive line L2 from the side of semiconductor substrate 11 serves as the upper conductive line of memory cell array M1 and the lower conductive line of memory cell array M2 and runs in the first direction. One end of conductive line L2 is connected to via ZIA2.

Conductive lines 21A to 21D and 22A to 22D are generally made of a metal material such as aluminum or copper. However, they are preferably made of a refractory metal such as tungsten to endure the high-temperature process.

Conductive lines L1, L2, L3, L4, L5, . . . in memory cell arrays M1, M2, M3, M4, M5, . . . and vias ZIA1, ZIA2, ZIA3, ZIA4, ZIA5, . . . are also preferably made of a refractory metal such as tungsten.

Conductive lines 23A and 23B on memory cell array 2 and dummy stacked layer structure 13 can be made of either a metal material such as aluminum or copper or a refractory metal such as tungsten.

### 4. Memory Cell Array and Dummy Stacked Layer Structure

### (1) First Embodiment

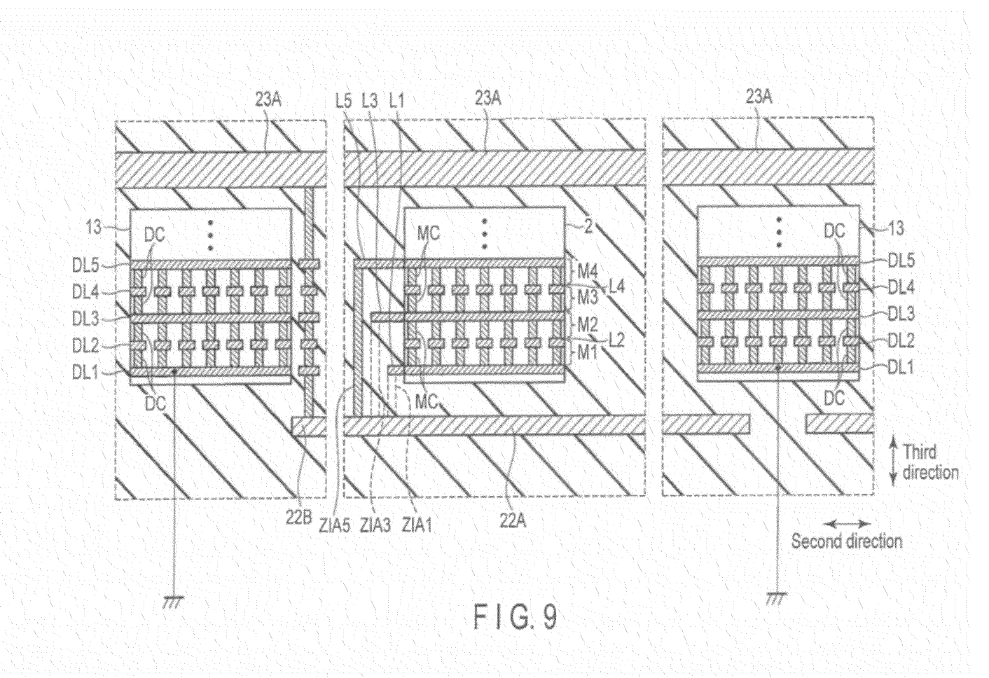

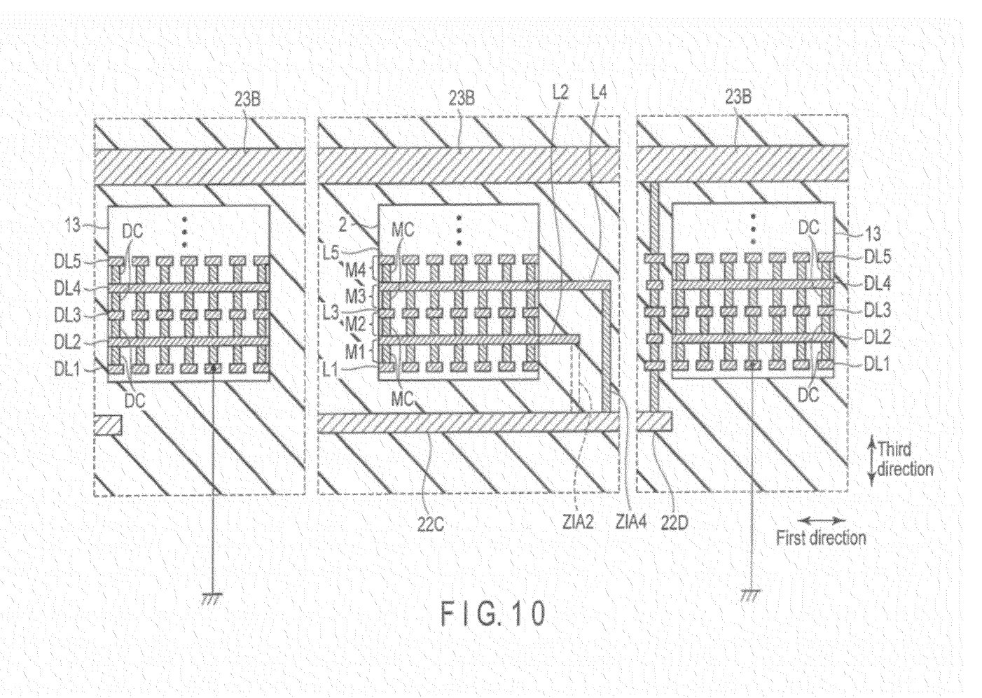

FIGS. 9 and 10 illustrate the memory cell array and the dummy stacked layer structure. FIG. 9 is a sectional view in the second direction, and FIG. 10 is a sectional view in the first direction.

In FIGS. 9 and 10, the same reference numerals denote the same elements as in FIGS. 6, 7, and 8.

Memory cell array 2 comprises memory cells MCs stacked on the semiconductor substrate, and conductive lines (first conductive layers) L1, L2, L3, L4, L5, . . . connected to memory cells MC.

Dummy stacked layer structure 13 comprises dummy cells DC stacked on the semiconductor substrate, and conductive lines (second conductive layers) DL1, DL2, DL3, DL4, DL5, . . . connected to dummy cells DC.

Dummy stacked layer structure 13 has, for example, the same structure as that of memory cell array 2. That is, conductive lines (first conductive layers) L1, L2, L3, L4, L5, . . . in memory cell array 2 and conductive lines (second conductive layers) DL1, DL2, DL3, DL4, DL5, . . . in dummy stacked layer structure 13 are made of the same material. In addition, memory cells MC and dummy cells DC are made of the same material (for example, a metal oxide for an ReRAM).

Dummy stacked layer structure 13 surrounds memory cell array 2.

Conductive lines (second conductive layers) DL1, DL2, DL3, DL4, DL5, . . . in dummy stacked layer structure 13 are fixed at the ground potential.

Vias ZIA1, ZIA2, ZIA3, ZIA4, ZIA5, . . . connect conductive lines (first conductive layers) L1, L2, L3, L4, L5, . . . in memory cell array 2 to conductive lines 22A and 22C.

Vias ZIA1, ZIA2, ZIA3, ZIA4, ZIA5, . . . have the same bottom surface position (reference point). Vias ZIA1, ZIA2, ZIA3, ZIA4, ZIA5, . . . gradually become longer in the third direction from via ZIA1 connected to conductive line L1 toward the via connected to the uppermost conductive line.

The running direction of odd-numbered conductive lines L1, L3, L5, . . . and the running direction of even-numbered conductive lines L2, L4, . . . are different. That is, drivers that drive odd-numbered conductive lines L1, L3, L5, . . . are provided together at one end of memory cell array 2 in the second direction. Drivers that drive even-numbered conductive lines L2, L4, . . . are provided together at one end of memory cell array 2 in the first direction.

According to the above-described arrangement, conductive lines (second conductive layers) DL1, DL2, DL3, DL4, DL5, . . . in dummy stacked layer structure 13 are fixed at the ground potential. This allows to prevent charges from being stored in dummy stacked layer structure 13.

Hence, neither a leak current from dummy stacked layer structure 13 nor an unnecessary coupling capacitance by dummy stacked layer structure 13 is generated during the write/erase/read operation, and a highly reliable three-dimensional nonvolatile semiconductor memory can be implemented.

Examples of the device structure that fixes the dummy stacked layer structure at the ground potential will be described next.

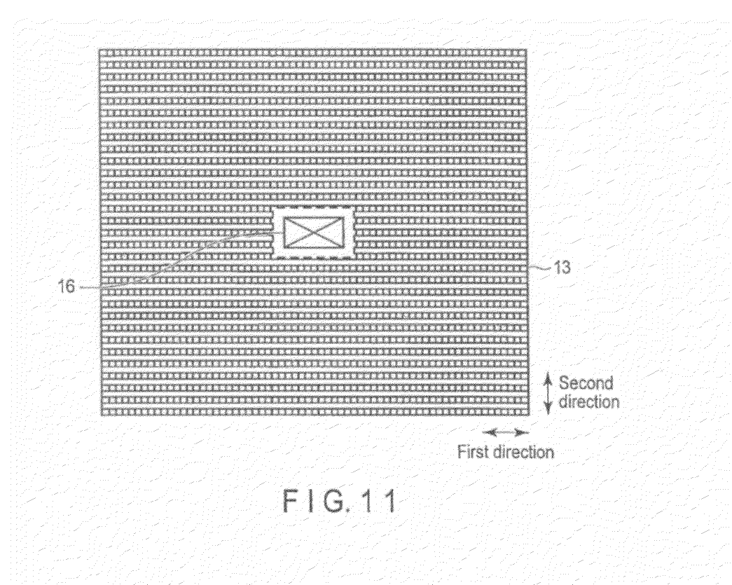

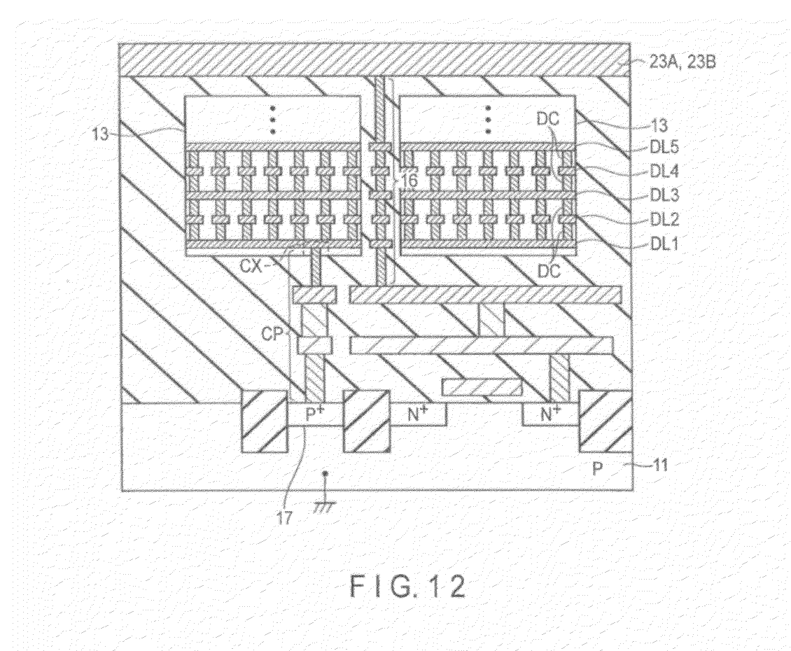

FIG. 11 is a plan view of the dummy stacked layer structure. FIGS. 12, 13, 14, and 15 are sectional views of the dummy stacked layer structure.

In the example of FIG. 12, heavily-doped diffusion layer 17 for contact with semiconductor substrate 11 is provided in semiconductor substrate (including the well region) 11 to which the ground potential is applied. Dummy stacked layer structure 13 has, in its bottom layer, contact portion CX for applying the ground potential to conductive lines (second conductive layers) DL1, DL2, DL3, DL4, DL5, . . . . Contact portion CX is connected to heavily-doped diffusion layer 17 through contact plug CP.

In this example, conductive lines (second conductive layers) DL1, DL2, DL3, DL4, DL5, . . . in dummy stacked layer structure 13 are biased to the ground potential from heavily-doped diffusion layer 17 in semiconductor substrate 11. It is therefore possible to prevent charges from being stored in the conductive lines.

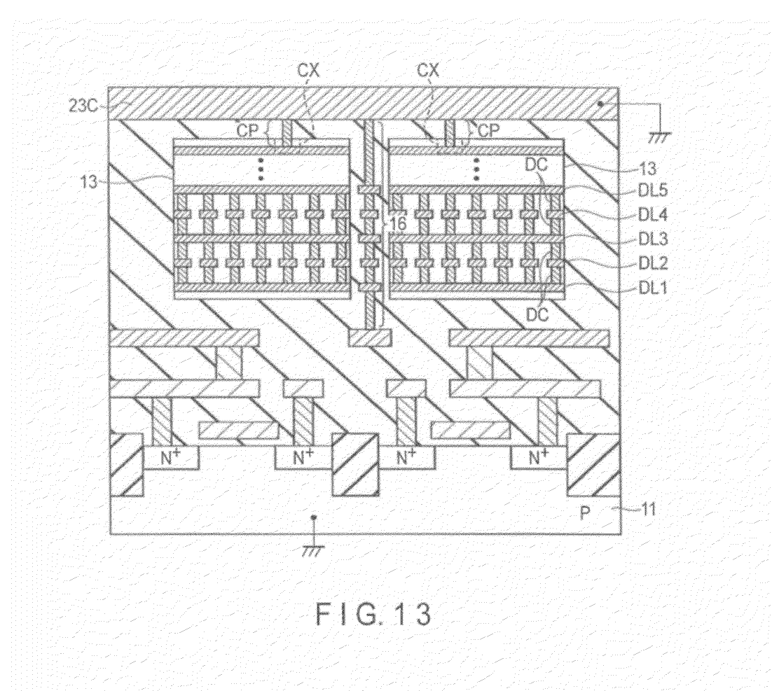

In the example of FIG. 13, dummy stacked layer structure 13 has, in its top layer, contact portions CX for applying the ground potential to conductive lines (second conductive layers) DL1, DL2, DL3, DL4, DL5, . . . . Contact portions CX are connected, through contact plugs CP, to conductive line (metal layer) 23C to which the ground potential is applied.

In this example, conductive lines (second conductive layers) DL1, DL2, DL3, DL4, DL5, . . . in dummy stacked layer structure 13 are biased to the ground potential from conductive line 23C. It is therefore possible to prevent charges from being stored in the conductive lines.

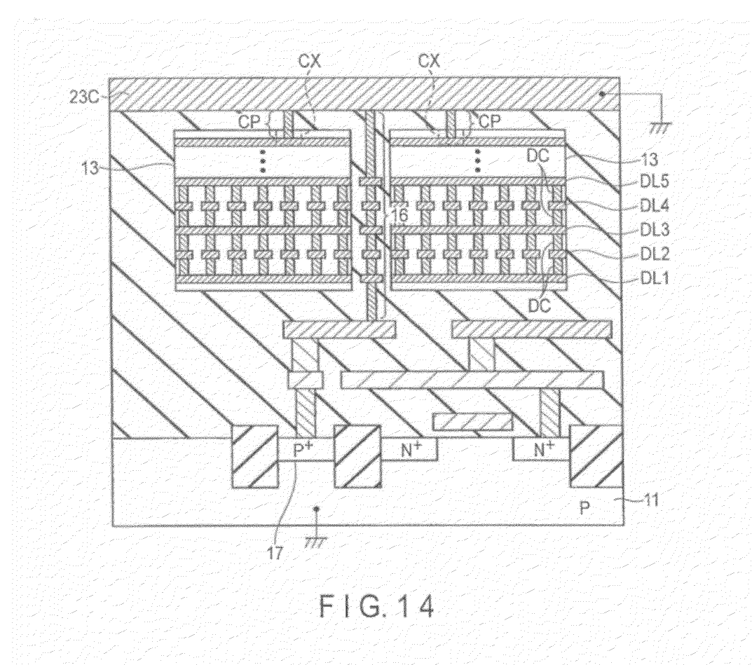

In the example of FIG. 14, heavily-doped diffusion layer 17 for contact with semiconductor substrate 11 is provided in semiconductor substrate (including the well region) 11 to which the ground potential is applied. Dummy stacked layer structure 13 has, in its top layer, contact portions CX for applying the ground potential to conductive lines (second conductive layers) DL1, DL2, DL3, DL4, DL5, . . . .

Contact portions CX are connected, through contact plugs CP, to conductive line (metal layer) 23C to which the ground potential is applied. In addition, conductive line 23C is connected to heavily-doped diffusion layer 17 in semiconductor substrate 11 through contact plug 16.

In this example, conductive lines (second conductive layers) DL1, DL2, DL3, DL4, DL5, . . . in dummy stacked layer structure 13 are biased to the ground potential from heavily-doped diffusion layer 17 and conductive line 23C. It is therefore possible to prevent charges from being stored in the conductive lines.

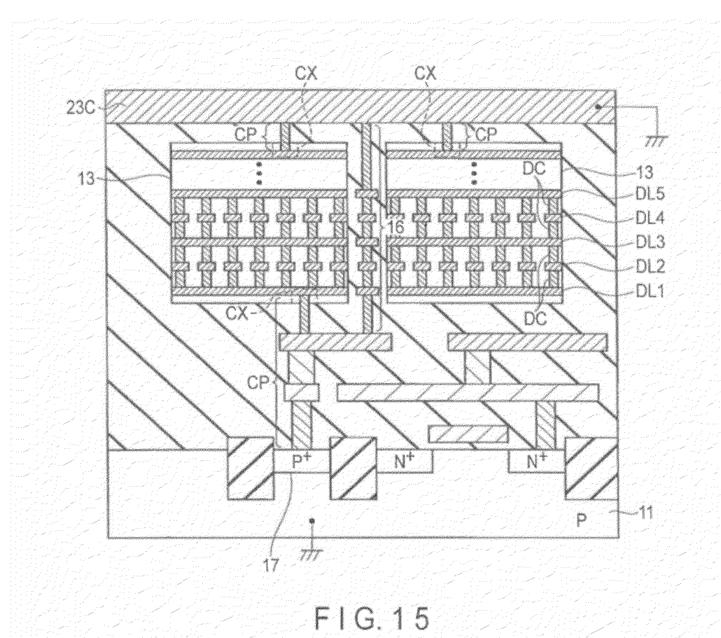

In the example of FIG. 15, heavily-doped diffusion layer 17 for contact with semiconductor substrate 11 is provided in semiconductor substrate (including the well region) 11 to which the ground potential is applied. Dummy stacked layer structure 13 has, in its bottom and top layers, contact portions CX for applying the ground potential to conductive lines (second conductive layers) DL1, DL2, DL3, DL4, DL5, . . . .

Contact portion CX in the bottom layer is connected to heavily-doped diffusion layer 17 through contact plug CP. Contact portions CX in the top layer are connected to conductive line (metal layer) 23C through contact plugs CP.

In this example as well, conductive lines (second conductive layers) DL1, DL2, DL3, DL4, DL5, . . . in dummy stacked layer structure 13 are biased to the ground potential from heavily-doped diffusion layer 17 and conductive line 23C. It is therefore possible to prevent charges from being stored in the conductive lines.

In the above-described examples, both semiconductor substrate 11 and heavily-doped diffusion layer 17 are of a p type. However, semiconductor substrate 11 may be of an n type, and heavily-doped diffusion layer 17 may be of a p type.

### (2) Second Embodiment

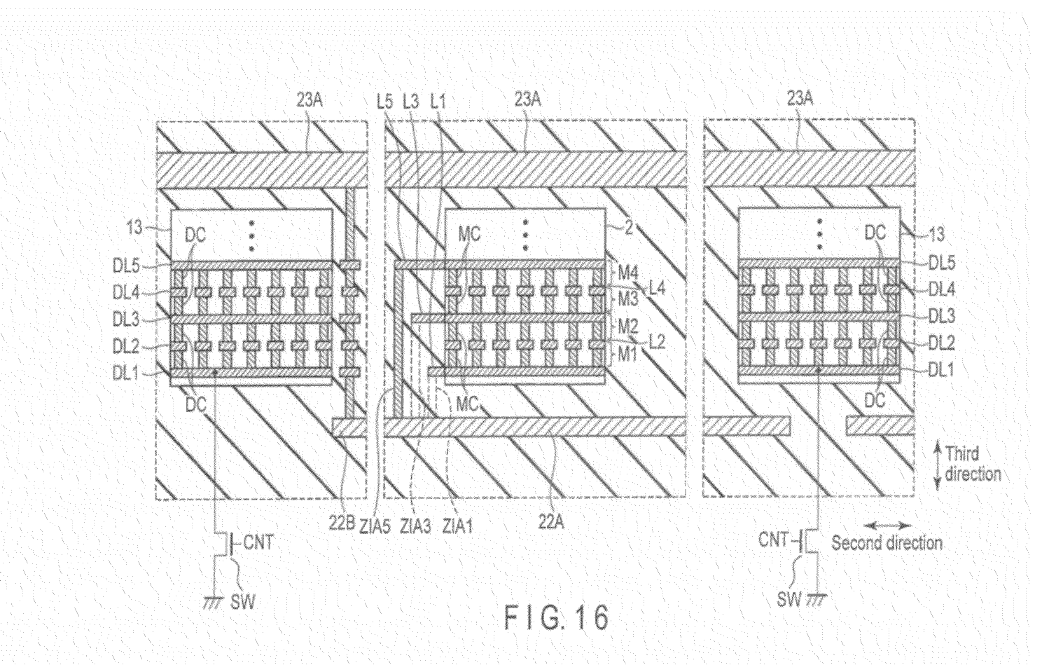

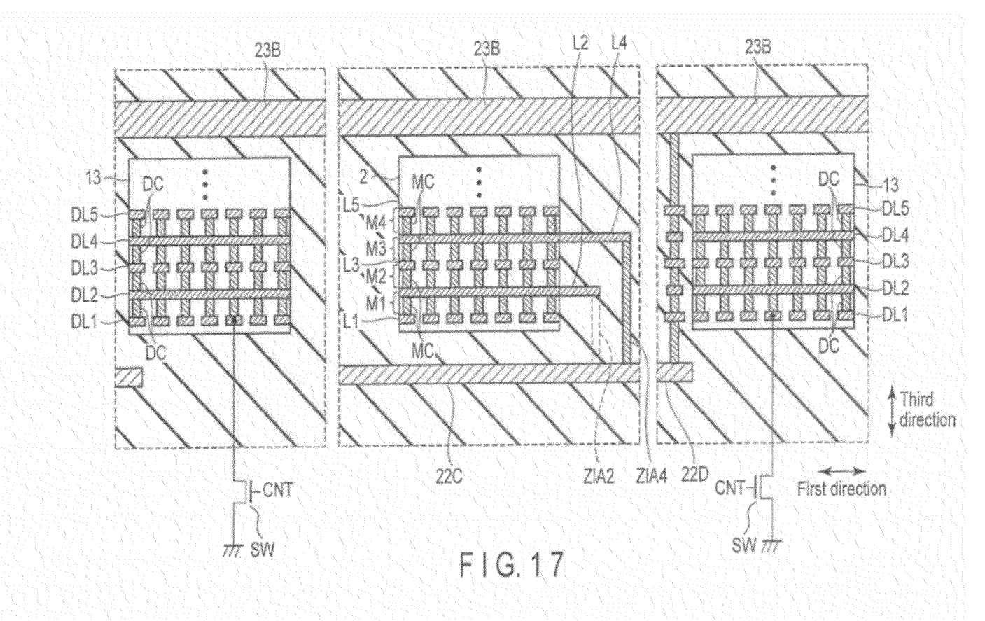

FIGS. 16 and 17 illustrate the memory cell array and the dummy stacked layer structure. FIG. 16 is a sectional view in the second direction, and FIG. 17 is a sectional view in the first direction.

In FIGS. 16 and 17, the same reference numerals denote the same elements as in FIGS. 6, 7, and 8.

In the second embodiment, conductive lines (second conductive layers) DL1, DL2, DL3, DL4, DL5, . . . in dummy stacked layer structure 13 are connected to ground potential Vss through switch elements SW, unlike the first embodiment. Switch elements SW are controlled to the ON state during a predetermined fixed period of time based on control signal CNT.

The remaining points are the same as in the first embodiment, and a detailed description thereof will be omitted.

According to the above-described arrangement, conductive lines (second conductive layers) DL1, DL2, DL3, DL4, DL5, . . . in dummy stacked layer structure 13 are fixed at the ground potential. This allows to prevent charges from being stored in dummy stacked layer structure 13.

Dummy stacked layer structure 13 is equivalent to a resistor having a very large resistance value. If the semiconductor substrate or a metal layer to which the ground potential is applied is always connected to dummy stacked layer structure 13, the potential of the semiconductor substrate or the metal layer may float (be higher than the ground potential).

Using switch elements SW to limit the period of time dummy stacked layer structure 13 is biased to the ground potential enables to prevent such an adverse effect. For example, switch elements SW can be turned on to bias dummy stacked layer structure 13 to the ground potential during a fixed period of time after power-on and turned off in the normal operation.

Hence, neither a leak current from dummy stacked layer structure 13 nor an unnecessary coupling capacitance by dummy stacked layer structure 13 is generated during the write/erase/read operation, and a highly reliable three-dimensional nonvolatile semiconductor memory can be implemented.

Examples of the device structure that fixes the dummy stacked layer structure at the ground potential will be described next.

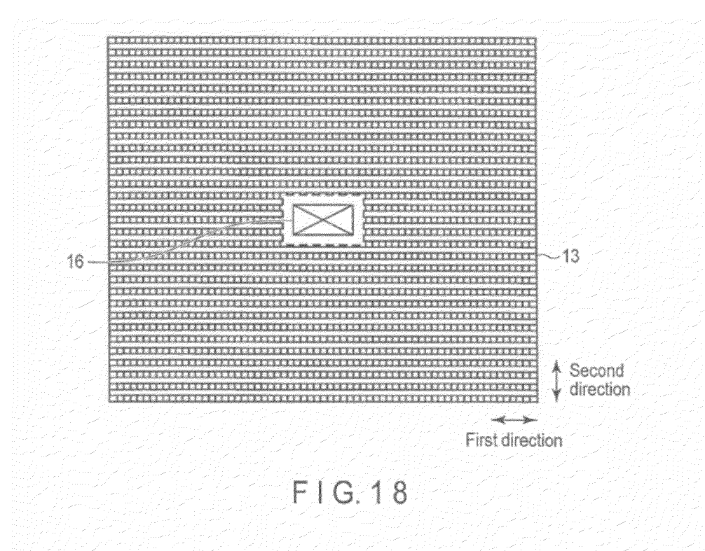

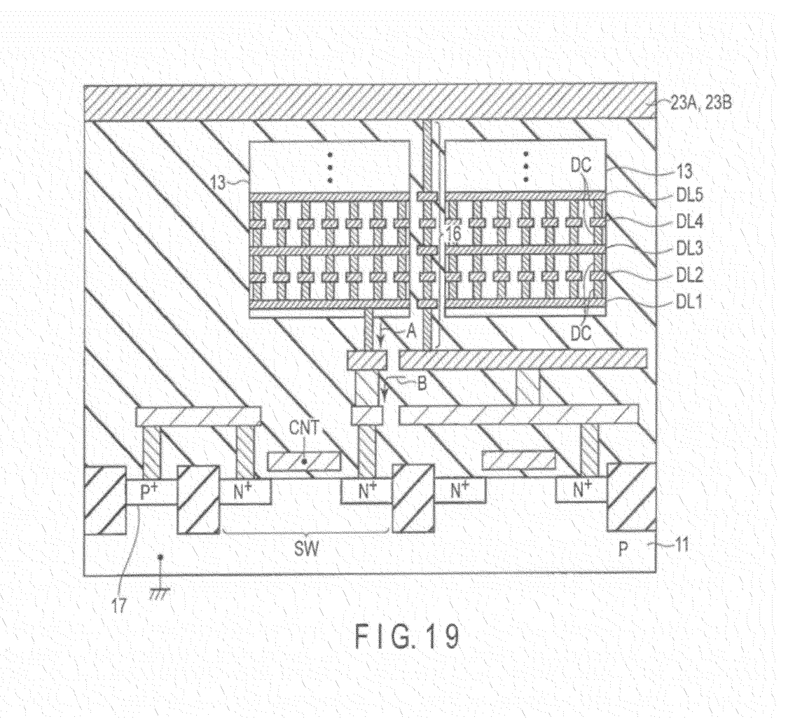

FIG. 18 is a plan view of the dummy stacked layer structure. FIGS. 19, 20, and 21 are sectional views of the dummy stacked layer structure.

In the example of FIG. 19, heavily-doped diffusion layer 17 for contact with semiconductor substrate 11 is provided in semiconductor substrate (including the well region) 11 to which the ground potential is applied. Dummy stacked layer structure 13 has, in its bottom layer, contact portion CX for applying the ground potential to conductive lines (second conductive layers) DL1, DL2, DL3, DL4, DL5, . . . .

Contact portion CX is connected to heavily-doped diffusion layer 17 through contact plug CP and switch element SW.

In this example, conductive lines (second conductive layers) DL1, DL2, DL3, DL4, DL5, . . . in dummy stacked layer structure 13 are biased to the ground potential from heavily-doped diffusion layer 17 in semiconductor substrate 11. It is therefore possible to prevent charges from being stored in the conductive lines.

Switch element SW is on/off-controlled by control signal CNT. If switch element SW is always on, leak path B from the adjacent interconnection may be generated in addition to discharge path A from dummy stacked layer structure 13. To prevent this, switch element SW is not always on, and is only on during a fixed period of time.

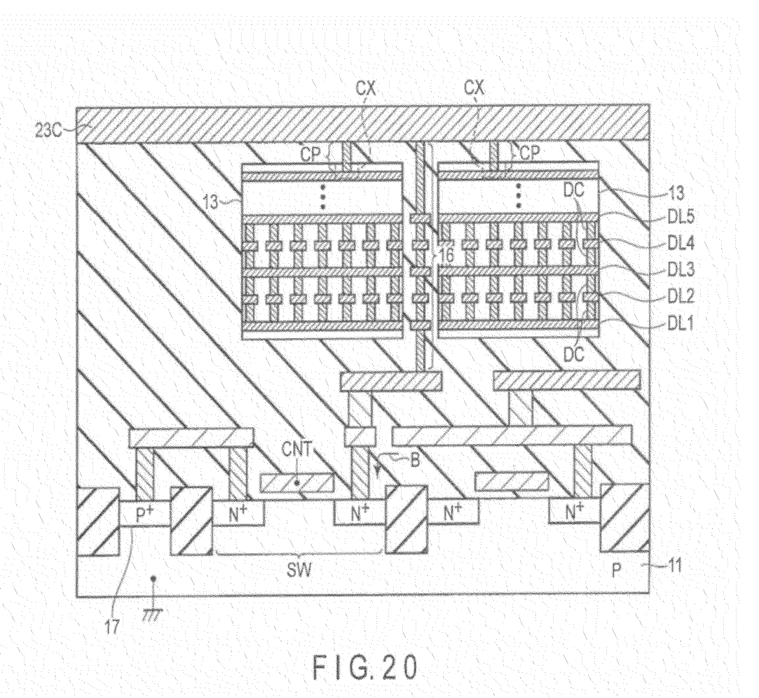

In the example of FIG. 20, heavily-doped diffusion layer 17 for contact with semiconductor substrate 11 is provided in semiconductor substrate (including the well region) 11 to which the ground potential is applied. Dummy stacked layer structure 13 has, in its top layer, contact portions CX for applying the ground potential to conductive lines (second conductive layers) DL1, DL2, DL3, DL4, DL5, . . . .

Contact portions CX are connected, through contact plugs CP, to conductive line (metal layer) 23C to which the ground potential is applied. In addition, conductive line 23C is connected to heavily-doped diffusion layer 17 in semiconductor substrate 11 through contact plug 16 and switch element SW.

In this example, conductive lines (second conductive layers) DL1, DL2, DL3, DL4, DL5, . . . in dummy stacked layer structure 13 are biased to the ground potential from heavily-doped diffusion layer 17 and conductive line 23C. It is therefore possible to prevent charges from being stored in the conductive lines.

In addition, turning switch element SW on during a predetermined fixed period of time enables to cut off leak path B from the adjacent interconnection.

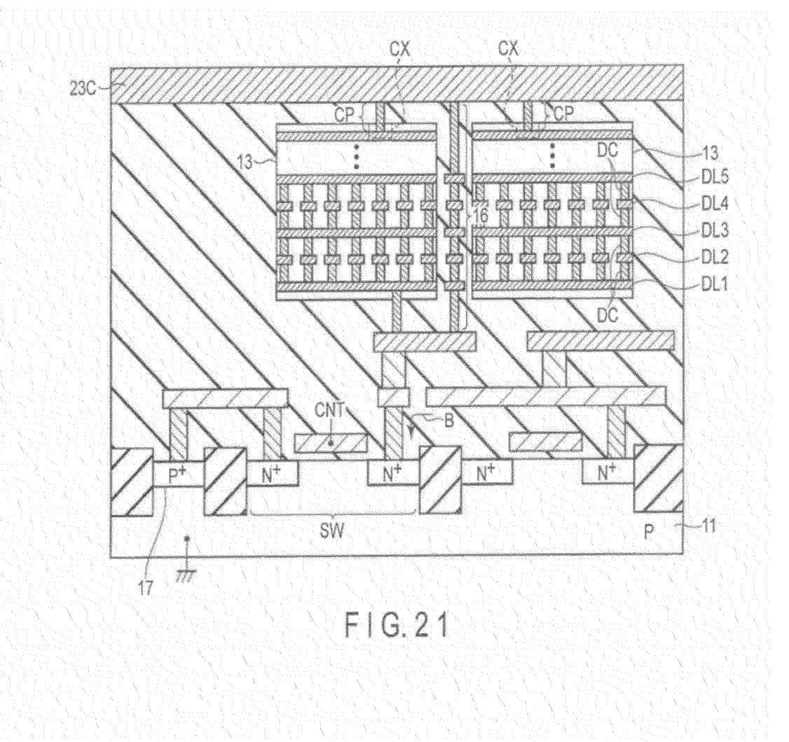

In the example of FIG. 21, heavily-doped diffusion layer 17 for contact with semiconductor substrate 11 is provided in semiconductor substrate (including the well region) 11 to which the ground potential is applied. Dummy stacked layer structure 13 has, in its bottom and top layers, contact portions CX for applying the ground potential to conductive lines (second conductive layers) DL1, DL2, DL3, DL4, DL5, . . . .

Contact portion CX in the bottom layer is connected to heavily-doped diffusion layer 17 through contact plug CP and switch element SW. Contact portions CX in the top layer are connected to conductive line (metal layer) 23C through contact plugs CP. In addition, conductive line 23C is connected to heavily-doped diffusion layer 17 through contact plug 16 and switch element SW.

In this example as well, conductive lines (second conductive layers) DL1, DL2, DL3, DL4, DL5, . . . in dummy stacked layer structure 13 are biased to the ground potential from heavily-doped diffusion layer 17 and conductive line 23C. It is therefore possible to prevent charges from being stored in the conductive lines.

In addition, turning on switch element SW during a predetermined fixed period of time enables to cut off leak path B from the adjacent interconnection.

In the above-described examples, both semiconductor substrate 11 and heavily-doped diffusion layer 17 are of a p type. However, semiconductor substrate 11 may be of an n type, and heavily-doped diffusion layer 17 may be of a p type.

### (3) Other

In the above-described first and second embodiments, when the contact portion of the dummy stacked layer structure is connected to conductive line (metal layer) 23C serving as a ground line, the conductive line 23C is preferably not used as the ground line of a peripheral circuit that needs a large current (several mA). This is because when a large current flows to the peripheral circuit, charges may flow into the dummy stacked layer structure through conductive line 23C.

More preferably, conductive line 23C is a dedicated line to be used to only remove charges from the dummy stacked layer structure.

### 5. Layout of Contact Portions of Dummy Stacked Layer Structure

Examples of the layout of contact portions for applying the ground potential to the conductive lines in the dummy stacked layer structure will be described.

### (1) FIRST EXAMPLE OF LAYOUT

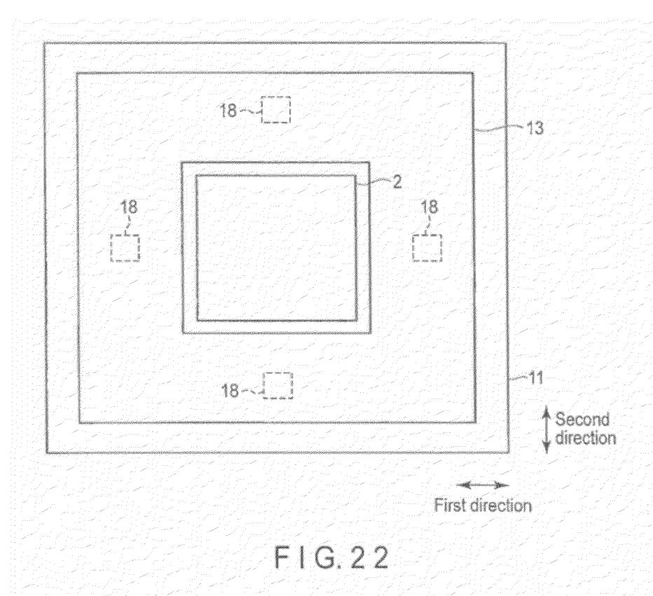

FIGS. 22, 23, 24, and 25 illustrate a first example of the layout of contact portions.

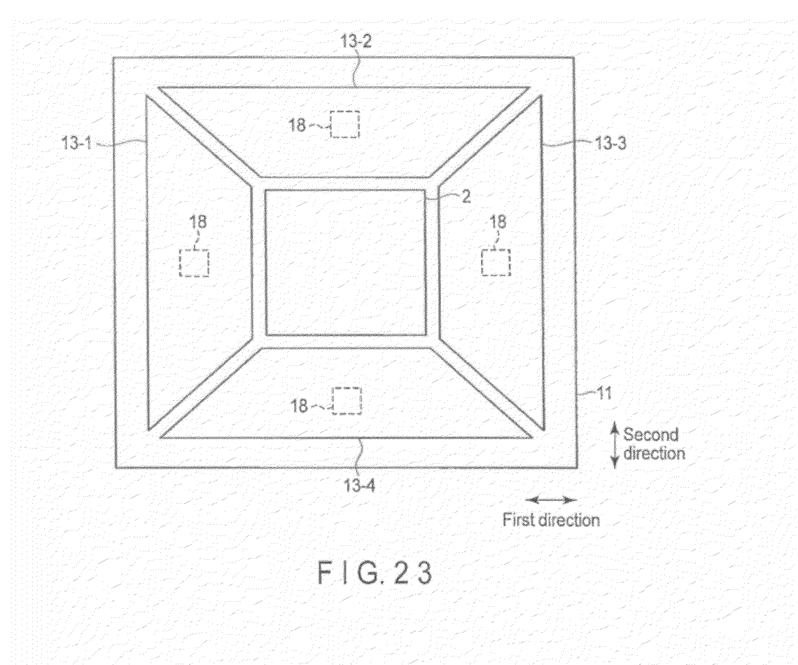

In the first example, as shown in FIGS. 22 and 23, memory cell array 2 and dummy stacked layer structure 13 (13-1, . . . , 13-4) are provided on semiconductor substrate 11. Dummy stacked layer structure 13 (13-1, . . . , 13-4) surrounds memory cell array 2.

In the example of FIG. 22, dummy stacked layer structure 13 has one ring pattern. In the example of FIG. 23, dummy stacked layer structures 13-1, . . . , 13-4 comprise four parts separated from each other. The contact portions of dummy stacked layer structure 13 (13-1, . . . , 13-4) are evenly laid out.

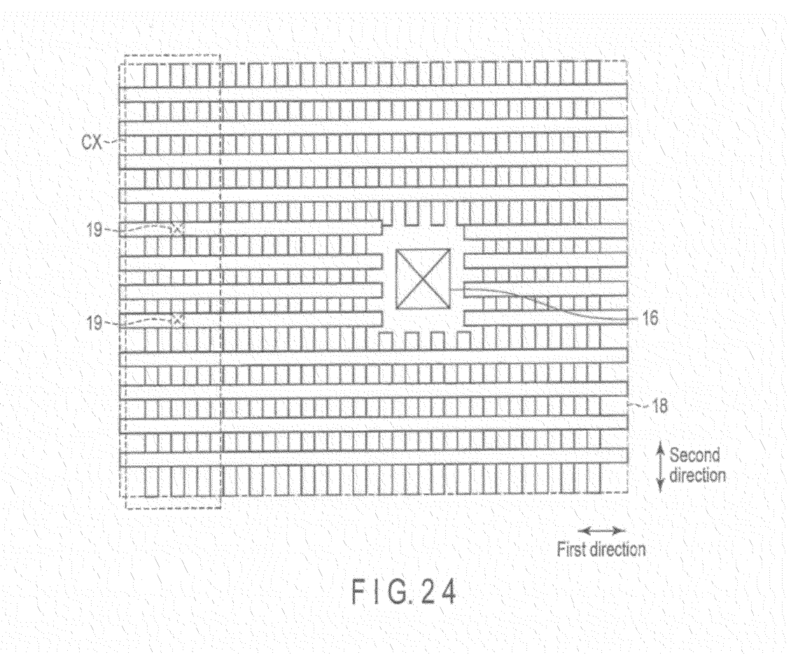

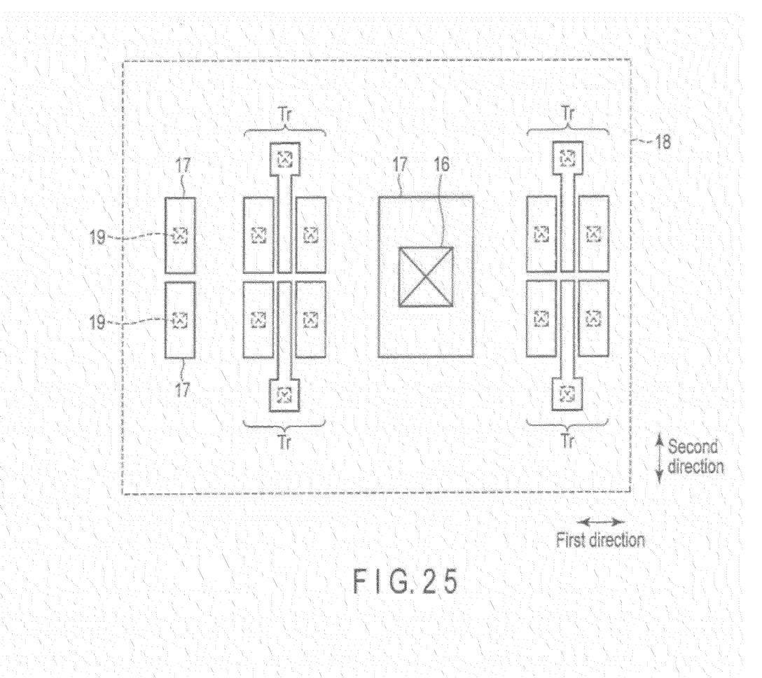

FIGS. 24 and 25 show details of area 18 in FIGS. 22 and 23. FIG. 24 shows the conductive lines in the dummy stacked layer structure. FIG. 25 shows heavily-doped diffusion layers 17 formed in the semiconductor substrate immediately below the dummy stacked layer structure.

Contact plug 16 is used to, for example, apply the ground potential to the semiconductor substrate (including the well region). Contact portions CX of the dummy stacked layer structure are connected to heavily-doped diffusion layers 17 through contact plugs 19.

Area 18 is an area where, for example, a control circuit is formed in the semiconductor substrate. In the three-dimensional nonvolatile semiconductor memory, the control circuits are dispersed in the semiconductor substrate. For this reason, part of the area where the control circuit is formed is preferably used to provide the heavily-doped diffusion layers 17 for applying the ground potential to the dummy stacked layer structure.

In this case, transistors (FET) Tr form part of the control circuit.

### (2) SECOND EXAMPLE OF LAYOUT

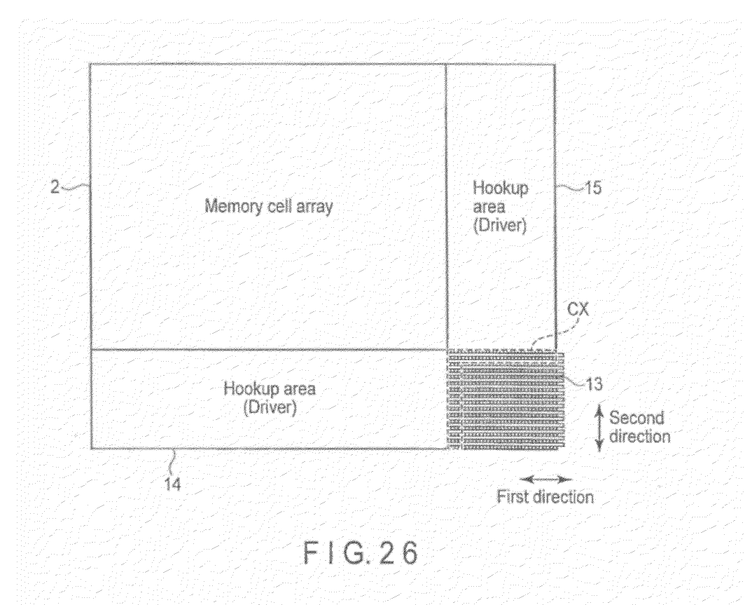

FIGS. 26, 27, and 28 illustrate a second example of the layout of contact portions.

In the second example, as shown in FIGS. 26, contact portion CX of dummy stacked layer structure 13 is provided at a corner portion of memory cell array 2.

Since hookup areas (drivers) 14 and 15 are provided at end portions in the first and second directions of memory cell array 2, a space relatively easily remains at the corner portion of memory cell array 2. Contact portion CX is provided in this space and connected to, for example, the heavily-doped diffusion layer in the semiconductor substrate. This makes it possible to bias dummy stacked layer structure 13 to the ground potential while suppressing an increase in the chip area.

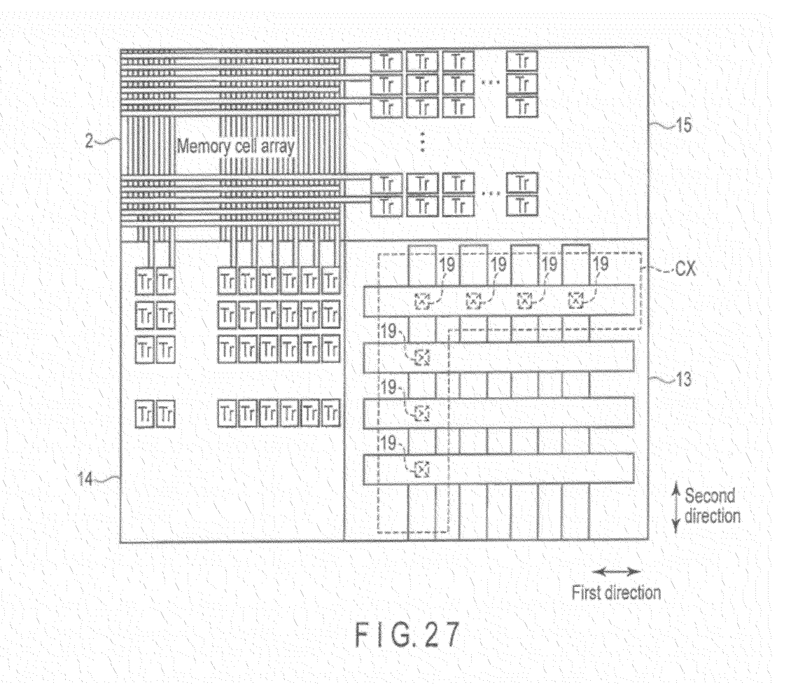

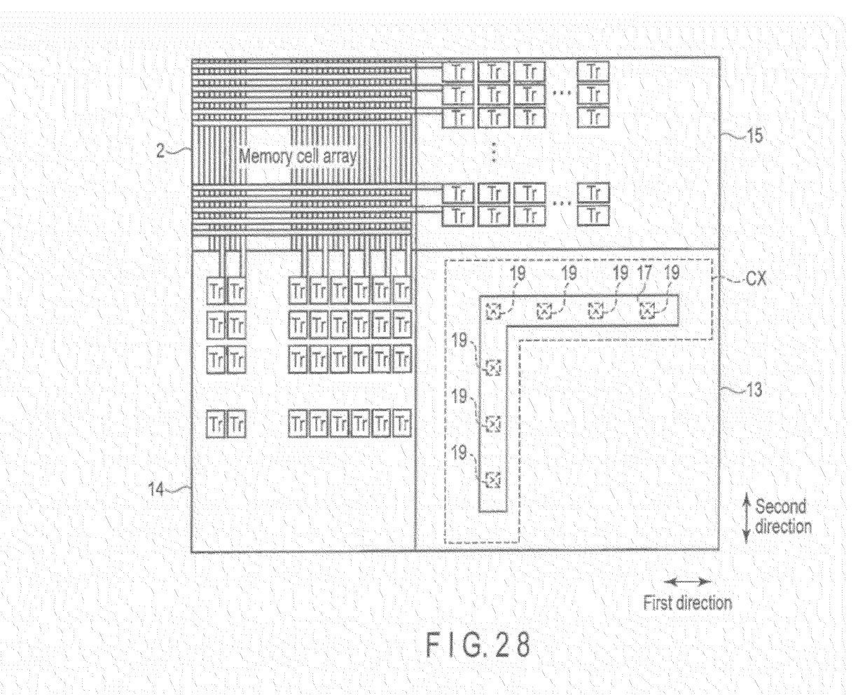

FIGS. 27 and 28 illustrate this state in detail.

Tr in hookup areas 14 and 15 represents a driver (for example, FET). Contact portion CX of dummy stacked layer structure 13 is connected to heavily-doped diffusion layer 17 via contact plugs 19.

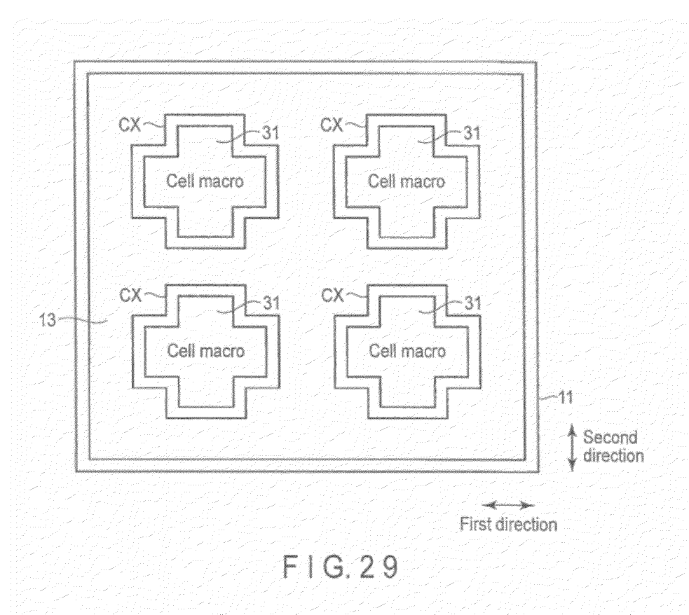

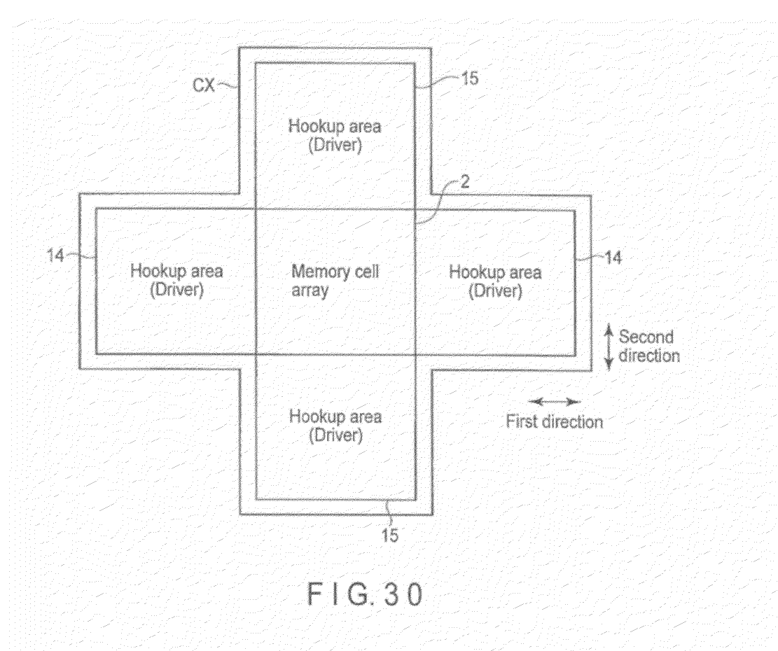

As shown in FIG. 29, for example, cell macros 31 are provided on semiconductor substrate (chip) 11. One cell macro comprises memory cell array 2 and hookup areas (drivers) 14 and 15, as shown in FIG. 30. In this example, hookup areas 14 are provided at two ends of memory cell array 2 in the first direction, and hookup areas 15 are provided at two ends of memory cell array 2 in the second direction.

In this case, contact portions CX of dummy stacked layer structure 13 may be provided in an area surrounding cell macro 31, as shown in FIGS. 29 and 30.

### (3) THIRD EXAMPLE OF LAYOUT

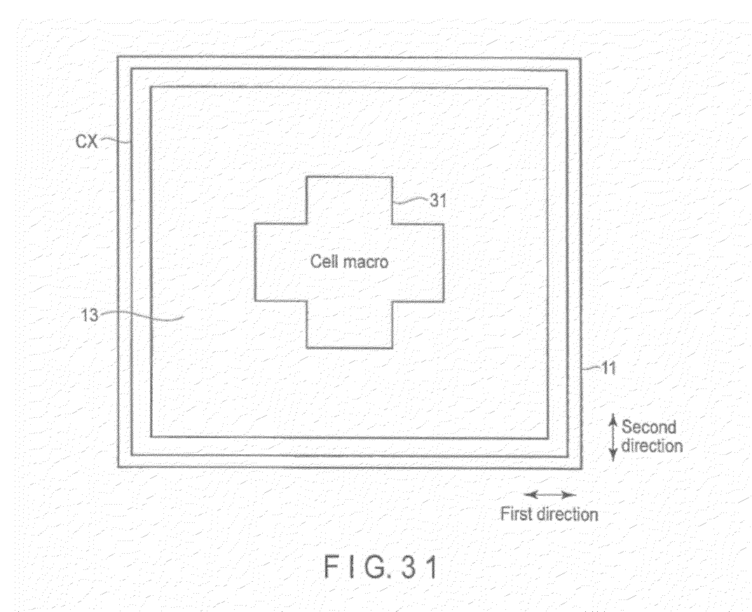

FIG. 31 illustrates a third example of the layout of contact portions.

In the third example, contact portion CX of dummy stacked layer structure 13 is provided in an area along the edge of semiconductor substrate (chip) 11.

In general, a pad is provided at the edge of a chip. Extra charges readily enter from the pad into dummy stacked layer structure 13. If contact portion CX exists at the edge of the chip, it can easily be connected to the ground line. In addition, a space relatively easily remains at the edge of the chip. It is therefore possible to bias dummy stacked layer structure 13 to the ground potential while suppressing an increase in the chip area.

### 6. BiCS-NAND

In the above embodiment, a resistance change memory has mainly been described. However, the technique of biasing the dummy stacked layer structure to the ground potential is also applicable to a BiCS-NAND.

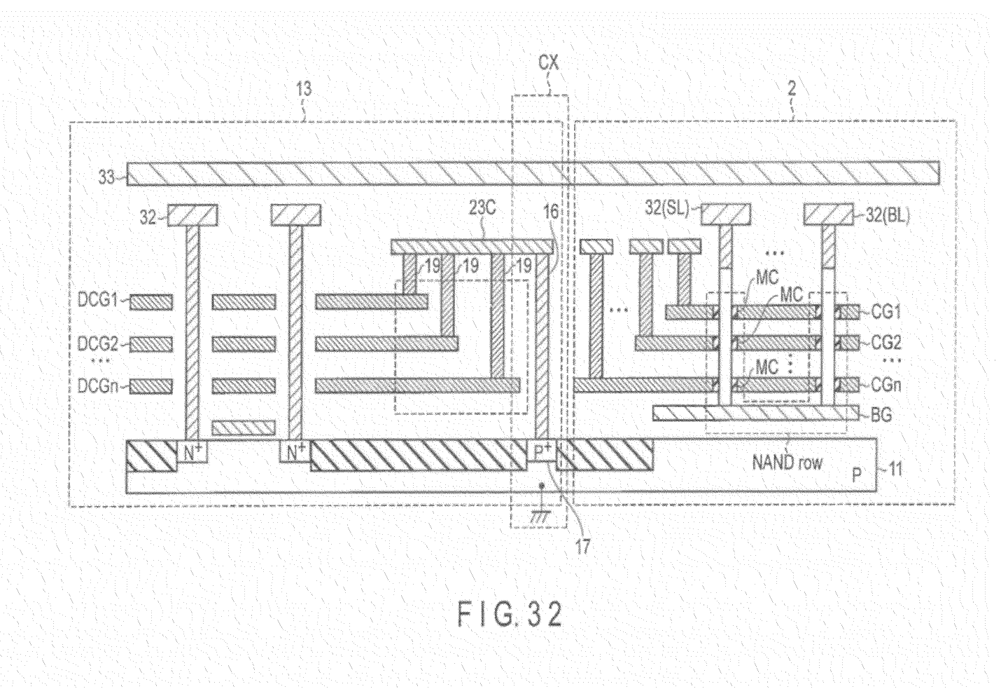

FIG. 32 shows the main part of a BiCS-NAND.

Memory cell array 2 comprises memory cells MC stacked on semiconductor substrate 11, and first conductive layers CG1, CG2, . . . , CGn connected to memory cells MC. Memory cells MC form a NAND-string.

In this example, the NAND-string is folded back by back gate BG in the bottom layer. However, the NAND-string structure is not limited to this. For example, the lower end of columnar active area AA extending through first conductive layers CG1, CG2, . . . , CGn may be open.

Each of memory cells MC includes a charge storage layer and a control gate electrode. First conductive layers CG1, CG2, . . . , CGn function as the control gate electrodes. One end of the NAND-string is connected to source line SL, and the other end is connected to bit line BL.

Although the structure is different from that of memory cell array 2, dummy stacked layer structure 13 comprises second conductive layers DCG1, DCG2, . . . , DCGn stacked on semiconductor substrate 11, like memory cell array 2.

Dummy stacked layer structure 13 surrounds memory cell array 2. Dummy stacked layer structure 13 is provided to planarize the upper surface of the insulating layer on memory cell array 2 and dummy stacked layer structure 13. For example, first metal layer 23C, second metal layer 32, and third metal layer 33 are provided on the insulating layer on memory cell array 2 and dummy stacked layer structure 13.

Second conductive layers DCG1, DCG2, . . . , DCGn in dummy stacked layer structure 13 are fixed at the ground potential.

In this example, dummy stacked layer structure 13 has contact portion CX for applying the ground potential to second conductive layers DCG1, DCG2, . . . , DCGn. Contact portion CX is electrically connected to heavily-doped diffusion layer 17 in semiconductor substrate 11 through contact plugs 16 and 19 and first metal layer 23C.

The method of biasing dummy stacked layer structure 13 to the ground potential is not limited to this. The method described concerning the resistance change memory is directly applicable. For example, in FIG. 32, a switch element may be connected between contact plug 16 and heavily-doped diffusion layer 17. Alternatively, first metal layer 23C may be used as a dedicated ground line for applying the ground potential to second conductive layers DCG1, DCG2, . . . , DCGn.

Note that in the example of FIG. 32, both semiconductor substrate 11 and heavily-doped diffusion layer 17 are of a p type. However, semiconductor substrate 11 may be of an n type, and heavily-doped diffusion layer 17 may be of a p type.

### 7. Conclusion

According to the embodiment, it is possible to prevent charges from being stored in the dummy stacked layer structure surrounding the memory cell array of the three-dimensional nonvolatile semiconductor memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A three-dimensional nonvolatile semiconductor memory comprising:
a semiconductor substrate;
a memory cell array comprising memory cells stacked on the semiconductor substrate and first conductive layers connected to the memory cells;
a dummy stacked layer structure comprising second conductive layers stacked on the semiconductor substrate, and surrounding the memory cell array; and
a metal layer provided on the memory cell array and the dummy stacked layer structure,
wherein the second conductive layers are fixed on a ground potential.

2. The memory of claim 1,
wherein the dummy stacked layer structure includes contact portions for applying the ground potential to the second conductive layers, and each of the contact portions is connected to at least one of the semiconductor substrate and the metal layer.

3. The memory of claim 2,
wherein the contact portions are evenly provided in the dummy stacked layer structure.

4. The memory of claim 2,
wherein the contact portions are provided in at least one of an area surrounding a cell macro and an area taking along an edge of a chip.

5. The memory of claim 1,
wherein the dummy stacked layer structure includes contact portions for applying the ground potential to the second conductive layers, and each of the contact portions is connected to the semiconductor substrate through a switch element.

6. The memory of claim 5,
wherein the switch element turns on during a fixed period of time.

7. The memory of claim 5,
wherein the contact portions are evenly provided in the dummy stacked layer structure.

8. The memory of claim 5,
wherein the contact portions are provided in at least one of an area surrounding a cell macro and an area taking along an edge of a chip.

9. The memory of claim 1, further comprising
a driver on the semiconductor substrate,
wherein the memory cell array and the dummy stacked layer structure are provided on the driver.

10. The memory of claim 1,
wherein the memory cell array and the dummy stacked layer structure have the same structure.

11. The memory of claim 1,
wherein the metal layer is connected to the top layer of the second conductive layers.

12. The memory of claim 1,
wherein the semiconductor substrate is connected to the bottom layer of the second conductive layers.

13. The memory of claim 1,
wherein the memory cells are resistance change elements.

14. The memory of claim 13,
wherein the memory cell array is a cross-point type memory cell.

15. The memory of claim 1,
wherein each of the memory cells has a charge storage layer, and the memory cells comprises a NAND-string.
